(19) United States
(12) Patent Application Publication
(10) Pub. No.: US 2026/0018572 A1
(43) Pub. Date: Jan. 15, 2026

(54) SEMICONDUCTOR DIE TRANSFER STRUCTURE WITH IMPROVED DIE RETENTION

(71) Applicant: Taiwan Semiconductor Manufacturing Company, LTD., Hsinchu (TW)

(72) Inventor: Po-Yu Chen, Hsinchu (TW)

(21) Appl. No.: 18/770,853

(22) Filed: Jul. 12, 2024

(51) Int. Cl. H01L 25/11; H01L 21/673

(52) U.S. Cl. CPC H01L 25/115; H01L 21/67333

(57) ABSTRACT

An assembly for semiconductor die transfer includes a carrier wafer, semiconductor dies oriented with proximal surfaces thereof facing the carrier wafer, and pillars comprising an organic polymer material supporting the semiconductor dies on the carrier wafer. The pillars have distal ends filling recesses in the proximal surfaces of the semiconductor dies. A semiconductor die of the semiconductor die transfer structure is picked up using a pick-and-place tool. To fabricate the structure, a dielectric layer is disposed on the proximal surfaces of the semiconductor dies, and openings are etched in the dielectric layer and the etching is continued into the proximal surfaces of the semiconductor dies to form the recesses therein. The dielectric layer is bonded to the carrier wafer using the organic polymer material which also fills the openings in the dielectric layer and the recesses in the proximal surfaces of the semiconductor dies. The dielectric layer is removed.

### BACKGROUND

The following relates to the semiconductor fabrication arts, semiconductor die transfer arts, semiconductor die placement arts, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A diagrammatically illustrates a top view of a semiconductor die transfer structure including semiconductor dies, which in this example are micro-light emitting diode (μLED) drivers, on a bottom holder, along with a diagrammatic side view of a pick-and-place tool used to transfer the μLED drivers from the semiconductor die transfer structure to a package surface, which in this example is a surface of an LED display; FIG. 1B diagrammatically illustrates a side sectional view of the pick-and-place tool in the process of picking up a target μLED driver from the semiconductor die transfer structure.

FIGS. 2A and 2B diagrammatically show a semiconductor die transfer structure, where: FIG. 2A diagrammatically shows a bottom view of a semiconductor die of the semiconductor die transfer structure viewed along View A-A indicated in FIG. 2B; and FIG. 2B diagrammatically shows a side sectional view of a portion of the semiconductor die transfer structure, including a representative die, viewed along Section B-B indicated in FIG. 2A.

FIGS. 3A and 3B diagrammatically show isolation views of the representative semiconductor die of the semiconductor die transfer structure of FIGS. 2A and 2B, where: FIG. 3A diagrammatically shows a bottom isolation view of the semiconductor die; and FIG. 3B diagrammatically shows a sectional isolation view of the semiconductor die taken along Section C-C indicated in FIG. 3A.

FIGS. 4A, 4B, 4C, 4D, and 4E diagrammatically show side sectional views at successive stages of fabrication of a semiconductor die transfer structure.

FIGS. 5A and 5B diagrammatically show isolation views of a representative semiconductor die of a semiconductor die transfer structure according to another embodiment, where: FIG. 5A diagrammatically shows a bottom isolation view of the semiconductor die; and FIG. 5B diagrammatically shows a sectional isolation view of the semiconductor die taken along Section D-D indicated in FIG. 5A.

FIGS. 6A and 6B diagrammatically show isolation views of a representative semiconductor die of a semiconductor die transfer structure according to another embodiment, where: FIG. 6A diagrammatically shows a bottom isolation view of the semiconductor die; and FIG. 6B diagrammatically shows a sectional isolation view of the semiconductor die taken along Section E-E indicated in FIG. 6A.

FIGS. 7A and 7B diagrammatically show isolation views of a representative semiconductor die of a semiconductor die transfer structure according to another embodiment, where: FIG. 7A diagrammatically shows a bottom isolation view of the semiconductor die; and FIG. 7B diagrammatically shows a sectional isolation view of the semiconductor die taken along Section F-F indicated in FIG. 7A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor dies manufactured at a semiconductor fabrication facility may be transported to a customer location, or a package assembly portion of the semiconductor fabrication facility, or the like, where the semiconductor dies are placed onto a package surface of a semiconductor device package under fabrication. The package surface may be a printed circuit board, a surface of an LED display, another semiconductor wafer or chip or die to assemble a multi-chip package, or so forth. In a commercial setting this transfer process may entail transferring a large number of semiconductor dies produced by dicing a semiconductor wafer on which a large number of integrated circuit (IC) dies or the like have been fabricated. Furthermore, the individual semiconductor dies being transferred may be small, e.g., a given semiconductor die may be a few microns or millimeters on a side. The transfer process is automated using a robotic or otherwise automated pick-and-place tool to provide fast semiconductor die transfer with minimal likelihood of contamination from human processing workers.

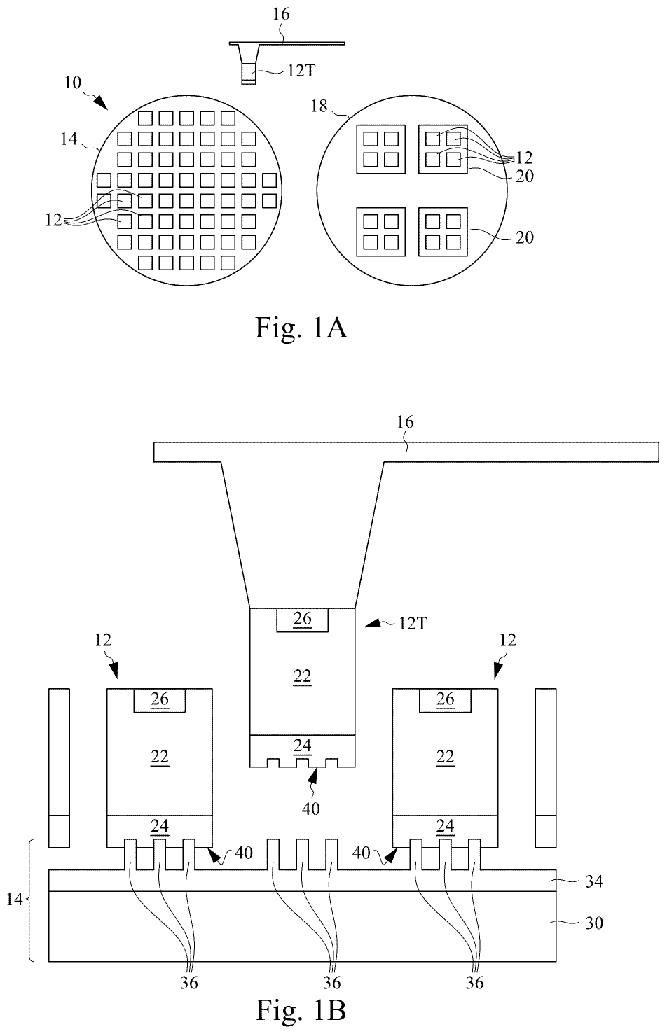

FIG. 1A diagrammatically illustrates a top view of a semiconductor die transfer structure 10 including semiconductor dies 12 disposed on a bottom holder 14. In this nonlimiting illustrative example, the semiconductor dies 12 are micro-light emitting diode (μLED) drivers (or more generically, LED drivers). More generally, however, the semiconductor dies 12 could be integrated circuit (IC) dies or other types of semiconductor dies. In the illustrative examples, the semiconductor dies 12 are silicon dies (that is, the IC, μLED driver, or other electronic or optoelectronic devices of the semiconductor dies 12 are fabricated in a silicon base material). However, the semiconductor dies 12 may be other types of semiconductor dies, such as gallium arsenide (GaAs) dies (that is, the IC, μLED driver, or other electronic or optoelectronic devices of the semiconductor dies 12 are fabricated in a GaAs base material), silicon germanium (Si₁₋ₓGeₓ) dies (that is, the IC, μLED driver, or other electronic or optoelectronic devices of the semiconductor dies 12 are fabricated in a Si₁₋ₓGeₓ base material), or so forth.

A pick-and-place tool 16 is used to transfer the semiconductor dies 12 from the semiconductor die transfer structure 10 to a package surface 18. In this nonlimiting illustrative example, the package surface 18 is a surface of an LED display, and the μLED drivers 12 are placed into 2×2 groupings 20 of four μLED drivers 12 each. Subsequently, red, green, blue, and white LEDs (e.g., μLEDs) will be placed onto the respective four μLED drivers 12 of each 2×2 grouping of μLED drivers 12 (step not shown) to form full-color pixels of the LED display under assembly. FIG. 1A shows the pick-and-place tool 16 in side view, carrying a target semiconductor die (e.g., μLED driver) 12T that has been picked up. It will be appreciated that this process will be repeated to transfer a large number (possibly all) of the semiconductor dies 12 from the semiconductor die transfer structure 10 to the package surface 18. While in the example the package surface 18 is a surface of an LED display, more generally the package surface 18 could be another package surface such as a printed circuit board, another semiconductor wafer or chip or die to assemble a multi-chip package, or so forth.

FIG. 1B diagrammatically illustrates a side sectional view of the pick-and-place tool 16 in the process of picking up the target semiconductor die 12T from amongst the semiconductor dies 12 of the semiconductor die transfer structure 10. In this nonlimiting illustrative example, each semiconductor die 12 is a μLED driver that includes a micro-driver component 22, such as a transistor or transistor-based LED driver, and which is optionally operatively coupled with optional additional electronic components or integrated circuitry 24. Each μLED driver further includes a top metal contact pad (or pads) 26 by which a μLED (not shown) electrically connects when the μLED is subsequently placed on the μLED driver 12. In some nonlimiting illustrative embodiments, the contact pad(s) 26 may be aluminum/copper (AlCu) pads, aluminum (Al) pads, copper (Cu) pads, or the like. Note that the illustrated configuration of components 22, 24, 26 is merely nonlimiting illustrative example, and that more generally the semiconductor dies 12 can be or include any type of semiconductor device, integrated circuit, or the like.

With continuing reference to FIG. 1B, the semiconductor die transfer structure 10 further includes the bottom holder 14 on which the semiconductor dies 12 are disposed. The illustrative bottom holder 14 includes a carrier wafer 30 coated with an organic polymer layer 34 made of an organic polymer material such as benzocyclobutene (BCB), and organic polymer pillars 36 made of an organic polymer material such as BCB. In the illustrative examples, the organic polymer layer 34 and the organic polymer pillars 36 are both made of the same organic polymer material (e.g., a BCB layer 34 and BCB pillars 36 in the illustrative examples); however, it is contemplated for the organic polymer pillars to be made of a different organic polymer material than the organic polymer layer. In the illustrative examples, the carrier wafer 30 is a silicon wafer; however, it is contemplated for the carrier wafer to be of another material, such as sapphire or gallium arsenide (GaAs). The semiconductor dies 12 are oriented with proximal surfaces 40 of the semiconductor dies 12 facing the carrier wafer. The pillars 36 support the semiconductor dies 12 on the carrier wafer 30 (via the intermediary organic polymer layer 34, in the embodiment of FIG. 1B).

The pick-and-place tool 16 picks up the target semiconductor die 12T by way of electrostatic attraction between the pick-and-place tool 16 and the target semiconductor die 12T. This has the advantage of not applying strong force to the potentially delicate target semiconductor die 12T, and not transferring adhesive or other bonding material onto the target semiconductor die 12T. However, it will be appreciated that the electrostatic attraction between the pick-and-place tool 16 and the target semiconductor die 12T is relatively weak. Hence, the bond of the target semiconductor die 12T to the bottom holder 14 should be weak enough that the electrostatic attraction to the pick-and-place tool 16 can overcome it and lift the target semiconductor die 12T off the bottom holder 14. A weak bond of the semiconductor dies 12 to the bottom holder 14 is achieved by using the pillars 36 to secure the semiconductor dies 12 to the bottom holder 14. The pillars 36 provide a relatively small contact area with the proximal surfaces 40 of the semiconductor dies 12, as compared with the larger contact area that would exist of the proximal surfaces 40 of the semiconductor dies 12 were to directly contact the continuous layer 34 of organic polymer material. The relatively small contact area provided by the pillars 36 provides a contact that can be overcome by the electrostatic attraction of the target semiconductor die 12T to the pick-and-place tool 16, in order to break the bonds of the proximal surface 40 of the target semiconductor die 12T with the pillars 36, as seen in FIG. 1B.

On the other hand, the bonds of the semiconductor dies 12 to the bottom holder 14 should be strong enough so that semiconductor dies 12 do not inadvertently break away from the bottom holder 14. Such a semiconductor die break away event may be referred to as a flyer, and decreases effective device yield since any semiconductor die 12 that breaks away from the bottom holder 14 is likely to be lost, or at least damaged or potentially damaged and hence deemed unusable. The relatively low bond strength provided by the pillars 36, while advantageously facilitating electrostatic pickup by the pick-and-place tool 16, also can have the disadvantage of contributing to increased occurrences of fliers.

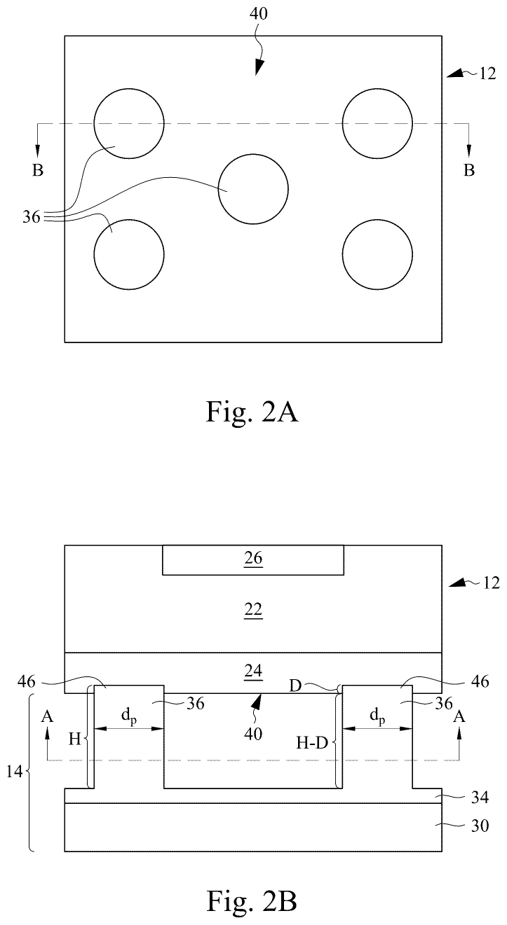

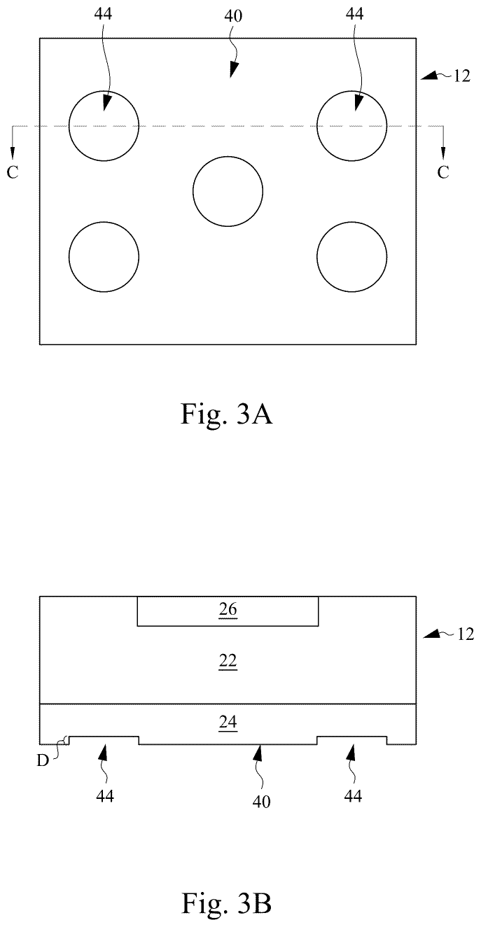

With continuing reference to FIGS. 1A and 1B and with further reference now to FIGS. 2A, 2B, 3A, and 3B, the likelihood of fliers is suppressed by providing recesses 44 in the proximal surfaces 40 of the semiconductor dies 12, and having distal ends 46 of the pillars 36 filling the recesses 44 in the proximal surfaces 40 of the semiconductor dies 12. (Note that FIGS. 2B and 3B illustrate the semiconductor die 12 with a different aspect ratio compared with FIG. 1B, to illustrate that the disclosed semiconductor dies and die transfer assemblies are not limited to semiconductor dies with any particular die aspect ratio.) FIG. 2A diagrammatically shows a bottom view of a semiconductor die 12 of the semiconductor die transfer structure 10 viewed along View A-A indicated in FIG. 2B. Conversely, FIG. 2B diagrammatically shows a side sectional view of a portion of the semiconductor die transfer structure 10, including a representative semiconductor die 12, viewed along Section B-B indicated in FIG. 2A. FIGS. 3A and 3B diagrammatically shows isolation views of the representative semiconductor die 12 of the semiconductor die transfer structure 10 of FIGS. 2A and 2B, where: FIG. 3A diagrammatically shows a bottom isolation view of the semiconductor die 12; and FIG. 3B diagrammatically shows a sectional isolation view of the semiconductor die 12 taken along Section C-C indicated in FIG. 3A. The isolation views of the semiconductor die 12 in FIGS. 3A and 3B illustrate the recesses 44 in the proximal surface 40 of the illustrative semiconductor die 12. As indicated in FIG. 3B, the recesses 44 have a depth D labeled in FIG. 3B. FIG. 3A shows a nonlimiting illustrative embodiment in which there are five recesses 44 in the proximal surface 40 of the illustrative semiconductor die 12, so that the pillars 36 engaging the recesses 44 (as shown in FIGS. 2A and 2B) provide balanced support for the illustrative semiconductor die 12 on the bottom holder 14. While five recesses 44 in the proximal surface 40 of the illustrative semiconductor die 12 are illustrated, this is merely a nonlimiting illustrative example and more generally the number of recesses 44 and corresponding supporting pillars 36 can be two, three, four, five, six, seven, or more, and can have various geometric arrangements.

FIGS. 2A and 2B illustrate the pillars 36 supporting the illustrative semiconductor die 12. As seen particularly in FIG. 2B, the distal end 46 of each pillar 36 fills a corresponding recess 44 in the proximal surface 40 of the supported semiconductor die 12. The distal ends 46 of the organic polymer pillars 36 thus engage into the recesses 44 in the proximal surface 40 of the semiconductor die 12. For a given diameter or other cross-sectional size of the pillars 36, this arrangement in which the distal ends 46 of the pillars 36 engage into respective recesses 44 in the proximal surface 40 of the semiconductor die 12 advantageously increases the total contact surface area between the distal ends 46 of the organic polymer pillars 36 and the silicon or other material of the proximal surface 40 of the semiconductor die 12, as compared with if the recesses 44 were omitted and the distal ends of the organic polymer pillars abutted a flat proximal surface of the semiconductor die.

For example, if each pillar 36 has a diameter dₚ then without the recess 44 this pillar would have a total contact area of

$$\frac{π}{2} \cdot {d}_{p}^{2} .$$

With the recess 44 of recess depth D, this contact area is increased to

$$\frac{π}{2} \cdot {d}_{p}^{2} + π \cdot {d}_{p} \cdot h ,$$

where the additional contact area π·dₚ·h is the lateral area of the cylinder of the recess 44. Furthermore, the arrangement in which the distal ends 46 of the pillars 36 engage into respective recesses 44 in the proximal surface 40 of the semiconductor die 12 can further increase the strength of retention of the semiconductor die 12 on the bottom holder 14 by the three-dimensional surface contact geometry (i.e., contact both at the tops of the distal ends 46 and on the lateral sides of the distal ends 46).

Thus, the arrangement in which the distal ends 46 of the pillars 36 fill corresponding recesses 44 in the proximal surfaces 40 of the supported semiconductor dies 12 (that is, the distal ends 46 of the organic polymer pillars 36 engage into the recesses 44 in the proximal surfaces 40 of the semiconductor dies 12) advantageously increases the retention strength of the semiconductor dies 12 on the bottom holder 14. This reduces flier defects and increases yield of the transfer of the semiconductor dies 14 from the semiconductor die transfer structure 10 to the package surface 18.

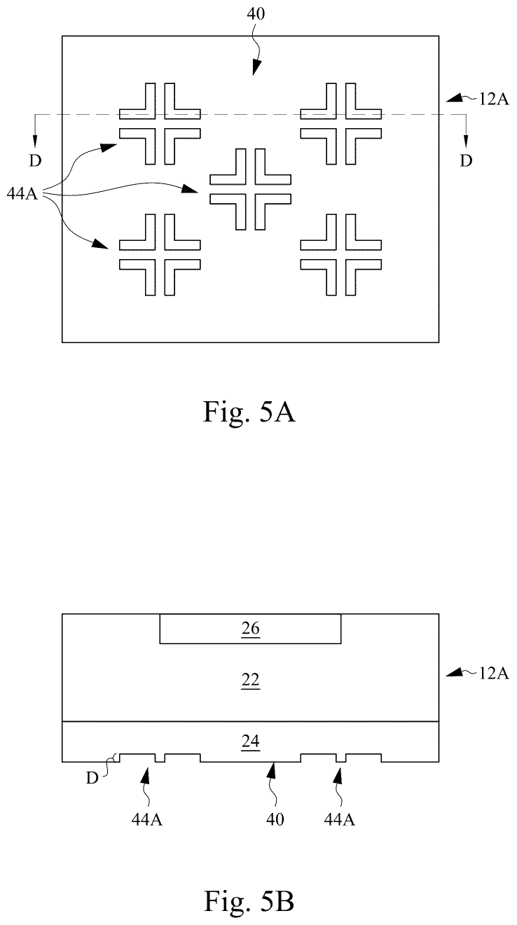

A further advantage of this approach is that the additional retention force provided by the recesses 44 in the proximal surface 40 of the semiconductor die 12 can be adjusted by adjusting the depth D of the recesses 44, and/or by adjusting the geometry of the recesses as described later herein with reference to FIGS. 5A, 5B, 6A, 6B, 7A, and 7B. This is advantageous because it enables tailoring the retention force to balance reduction (or elimination) of flier defects with ensuring the retention force is not so strong as to prevent the pick-and-place tool 16 (see FIGS. 1A and 1B) from being able to reliably pick up the semiconductor dies 12 from the semiconductor die transfer structure 10 by the relatively weak electrostatic attraction of the semiconductor dies 12. In some embodiments, the recesses 44 in the proximal surfaces 40 of the semiconductor dies 12 have depth D that is greater than zero and is 6 microns or less. In some embodiments, the recesses 44 in the proximal surfaces 40 of the semiconductor dies 12 have depth D of between 0.5 micron and 6 microns. It is expected that these depth ranges will provide a suitable balance between minimizing or eliminating fliers (by increased retention force) and enabling reliable pickup of the semiconductor dies 12 by the pick-and-place tool 16 (by ensuring the retention force is not too strong). However, it will be appreciated that these illustrative depth ranges are not limiting, and that larger or smaller values of the depth D of the recesses 44 in the proximal surfaces 40 of the semiconductor dies 12 are contemplated. For example, if the diameter dₚ of the organic polymer pillars 36 is made smaller in a particular design of the semiconductor die transfer structure 10, then a larger value of recess depth D may be employed to compensate for the reduction in retention produced by the smaller diameter of the organic polymer pillars 36. As another example, if the semiconductor dies 12 are larger in area then more retention force may be provided by increasing the recess depth D (while, the larger semiconductor dies may provide for higher electrostatic attraction so that the increased retention force provided by the increased recess depth D may not adversely impact reliability of the pickup of the semiconductor dies 12 by the pick-and-place tool 16). These are merely some nonlimiting example recess depth ranges and some possibly relevant criteria for optimizing the recess depth for a particular semiconductor die transfer structure 10, and it will be appreciated that the recess depth D can also be empirically optimized for a given semiconductor die transfer structure 10 by constructing test semiconductor die transfer structures with different values of the recess depth D and experimentally assessing flier rates and efficacy of pickup of the semiconductor dies using the pick-and-place tool.

With particular reference to FIG. 2B, if the organic polymer pillars 36 have a total height H from the connection of the pillars with the continuous layer 34 of the organic polymer material to the (extreme tips of) distal ends 46 of the pillars 36, and the recesses 44 in the proximal surfaces 40 of the semiconductor dies 12 have depth D, then the organic polymer pillars 36 space the proximal surfaces 40 of the semiconductor dies 12 from the continuous layer 34 of the organic polymer material by a distance H-D, as labeled in FIG. 2B. In some nonlimiting illustrative examples, the organic polymer pillars 36 may have diameter d_{P} of between 0.5 micron and 0.7 micron, but this is merely a nonlimiting example. In some nonlimiting illustrative examples, the continuous layer 34 of organic material may have a thickness in a range of 3 microns to 5 microns, but again this is merely a nonlimiting example.

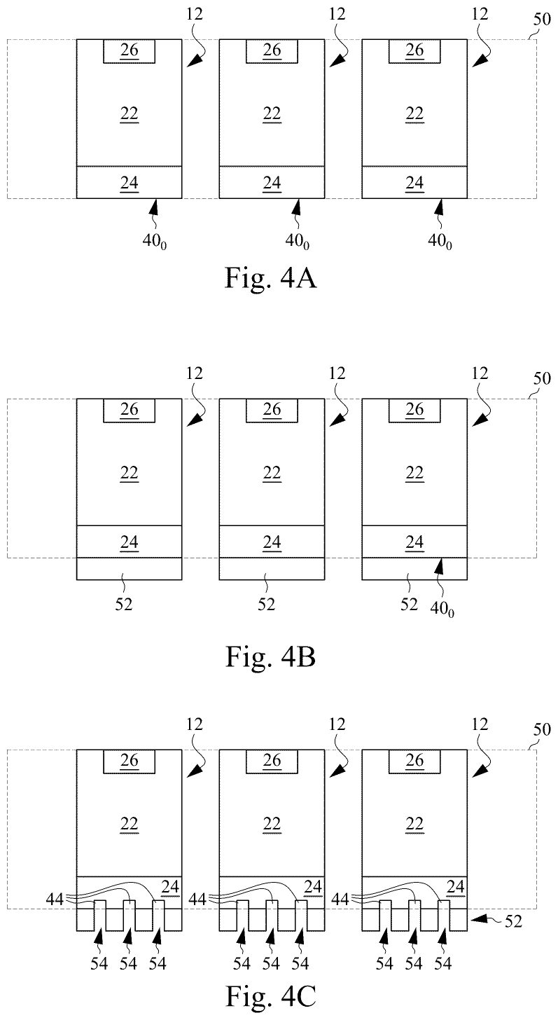

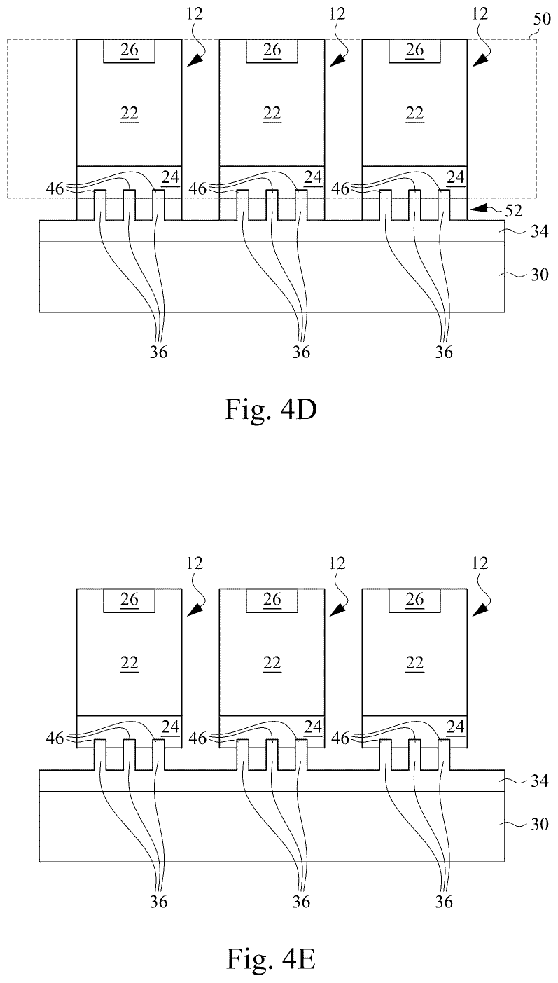

With reference now to FIGS. 4A, 4B, 4C, 4D, and 4E, a nonlimiting example of an approach for fabricating the semiconductor die transfer structure 10 is diagrammatically shown by way of side sectional views at successive stages of fabrication of a semiconductor die transfer structure 10.

FIG. 4A illustrates the manufactured semiconductor dies 12. The manufactured semiconductor dies 12 are substantially similar to the semiconductor dies 12 of the final semiconductor die transfer structure 10, except that they have planar proximal surfaces 400 (where the planar proximal surfaces 400 correspond to the proximal surfaces 40 of the final semiconductor die transfer structure 10. At the fabrication stage of FIG. 4A the semiconductor dies 12 have planar proximal surfaces 400 because the recesses 44 have not yet been formed. The illustrative semiconductor dies 12 as shown in FIG. 4A are fully fabricated as they include the micro-driver 22, optional additional electronic components or integrated circuitry 24, and top metal contact pad(s) 26.

One other optional difference with the semiconductor dies 12 of the final semiconductor die transfer structure 10 is that at the manufacturing stage of FIG. 4A the semiconductor dies 12 may not yet have been singulated (e.g., diced using a dicing saw, laser cutting, or the like). This is diagrammatically indicated by a wafer 50 indicated by a dashed line in FIG. 4A. For example, the wafer 50 could be a silicon wafer on and/or in which the semiconductor dies 12 were manufactured. In some such embodiments, the wafer 50 may be thinned or otherwise processed (in addition to the processing that formed the semiconductor dies 12).

With reference to FIG. 4B, a dielectric layer 52 is disposed on the planar proximal surfaces 400 of the semiconductor dies 12. If the semiconductor dies 12 are not yet singulated, then the dielectric layer 52 is suitably disposed as a continuous layer over the entire corresponding surface of the wafer 50. The dielectric layer 52 may be an oxide, such as silicon dioxide (SiO₂), silicon oxynitride (SiON), or the like, or may be a nitride such as silicon nitride (Si₃N₄), or so forth.

With reference to FIG. 4C, photolithographically controlled etching is performed to etch openings 54 in the dielectric layer 52. These openings 54 correspond to the destined pillars 36. The etching is continued into the (planar) proximal surface 400 to form the recesses 44 in the (final, non-planar) proximal surfaces 40 of the semiconductor dies 12. If the semiconductor dies 12 are not yet singulated at the stage of processing shown in FIG. 4C, then the etching is performed on the continuous dielectric layer 52 spanning the corresponding surface of the wafer 50, with the openings 54 in the dielectric layer 52 being etched at the locations corresponding to the destined organic polymer pillars 36 of the final semiconductor die transfer structure 10.

The etching to form the openings 54 in the dielectric layer 52, and which is continued to form the recesses 44 in the proximal surfaces 40 of the semiconductor dies 12, can be performed in various ways. In one approach, a photolithography mask is formed by photoresist deposition, photolithographic exposure, and development so that the developed photomask has openings corresponding to the openings 54. Thereafter, wet or dry etching is performed to using the developed photomask to limit the etching to the openings 54. The etchant is effective for etching the dielectric material of the dielectric layer 52. If the etchant is also effective for etching the silicon (or other material) of the proximal surfaces 40 of the semiconductor dies 12, then the etching can be timed to etch the openings 54 passing completely through the dielectric layer 52 and to further etch into the proximal surfaces 40 of the semiconductor dies 12 to form the recesses 44 in the proximal surfaces 40 of the semiconductor dies 12. In this approach, the openings 54 passing through the dielectric layer 52 are self-aligned with the recesses 44 in the proximal surfaces 40 of the semiconductor dies 12.

In a variant approach, the etching to form the openings 54 passing through the dielectric layer 52 can be ineffective to etch the material of the proximal surfaces 40 of the semiconductor dies 12, in which case the planar proximal surfaces 400 of the semiconductor dies 12 serves as an etch stop for the etching of the openings 54 passing through the dielectric layer 52. Thereafter, a different wet or dry etchant can be applied, which is effective to etch the material of the proximal surfaces 40 of the semiconductor dies 12, so as to form the recesses 44 in the proximal surfaces 40 of the semiconductor dies 12. In this second etch step the openings 54 passing through the dielectric layer 52 serve as a self-aligned mask to align the etched recesses 44 with the previously etched openings 54 passing through the dielectric layer 52.

These are some merely some nonlimiting illustrative approaches for etching the openings 54 in the dielectric layer 52 and continuing the etching into the proximal surfaces 40 of the semiconductor dies 12 to form the recesses 44 in the proximal surfaces 40 of the semiconductor dies 12. Other approaches are contemplated, such as employing a dedicated thin etch stop layer applied to the planar proximal surface 400 of the semiconductor dies 12 to provide etch depth control.

With reference now to FIG. 4D, the dielectric layer 52 (with the etched openings 54) is bonded to the carrier wafer 30 using the organic polymer material. The organic polymer material used in this bonding forms the continuous layer 34 of the organic polymer material. Additionally, during the bonding the organic polymer material also flows into and fills the openings 54 in the dielectric layer 52, and the organic polymer material continues to flow into and fills the recesses 44 in the proximal surfaces 40 of the semiconductor dies 12 to form the pillars 36 having distal ends 46 filling the recesses 44 in the proximal surfaces 40 of the semiconductor dies 12. If the semiconductor dies 12 are not yet singulated at the stage of processing shown in FIG. 4D, then the bonding constitutes wafer-wafer bonding of the wafer 50 containing or including the semiconductor dies 12 (and more particularly, the dielectric layer 52 disposed thereon) and the carrier wafer 30. Organic polymer materials such as BCB are effective for wafer-to-wafer or die-to-wafer bonding, and so the continuous organic polymer layer 34 provides a suitable bond of the semiconductor dies 12 (or the wafer 50) to the carrier wafer 30.

With reference to FIG. 4E, the dielectric layer 52 is removed to complete fabrication of the final semiconductor die transfer structure 10. This can be done, for example, using an etchant that is selective for etching the material of the dielectric layer 52 over etching the BCB or other organic polymer material constituting the continuous organic polymer layer 34 and organic polymer pillars 36. If the semiconductor dies 12 have not yet been singulated, this can be done using a dicing saw, laser cutting, or the like. If the singulation is done before the removal of the dielectric layer 52 then the dielectric layer 52 can provide structural support during the dicing, laser cutting, or the like; and moreover, the removed material during the singulation provides enhanced access of the selective etchant to reach and dissolve the dielectric layer 52.

It will be appreciated that the fabrication process described herein with reference to FIGS. 4A, 4B, 4C, 4D, and 4E is merely a nonlimiting illustrative example, and other manufacturing workflows or processes can be used to fabricate the semiconductor die transfer structure 10.

In the illustrative examples thus far, the organic polymer pillars 36 have circular cross-sections, and the recesses 44 in the proximal surfaces 40 of the semiconductor dies 12 have aligned circular cross-sections. However, the recesses in the proximal surfaces 40 of the semiconductor dies 12 can more generally be circular recesses (e.g., as in the recesses 44), annular recesses, cross-shaped recesses, parallel strip recesses, or other cross-sections.

For example, FIGS. 5A and 5B diagrammatically show isolation views of a representative semiconductor die 12A of a semiconductor die transfer structure 10 according to another embodiment. FIG. 5A diagrammatically shows a bottom isolation view of the semiconductor die 12A including the proximal surface 40 of the semiconductor die 12A, and FIG. 5B diagrammatically shows a sectional isolation view of the semiconductor die 12A taken along Section D-D indicated in FIG. 5A. The semiconductor die 12A of FIGS. 5A and 5B is identical to the semiconductor die 12 previously described, e.g., with reference to FIGS. 3A and 3B-except that recesses 44A in the proximal surface 40 of the semiconductor die 12A has a different cross-sectional geometry than the circular cross-section recesses 44 in the proximal surface 40 of the semiconductor die 12. The recesses 44A in the proximal surface 40 of the semiconductor die 12A are cross-shaped recesses. This advantageously increases the contact area between the silicon (or other material) of the proximal surface 40 of the semiconductor die 12A and the organic polymer of the distal ends 46 of the organic polymer pillars 36, thus (further) increasing the retention force holding the semiconductor die 12 to the bottom holder 14. The recesses 44A have an indicated recess depth D. In some embodiments, the cross-shaped recesses 44A have depth D that is greater than zero and is 6 microns or less. In some embodiments, the cross-shaped recesses 44A have depth D of between 0.5 micron and 6 microns. These are again merely nonlimiting illustrative examples of some suitable depths for certain specific implementations. The corresponding organic polymer pillars 36 may also have cross-shaped cross-sections matching the cross-shaped cross-section of the recesses 44A, although this is not required.

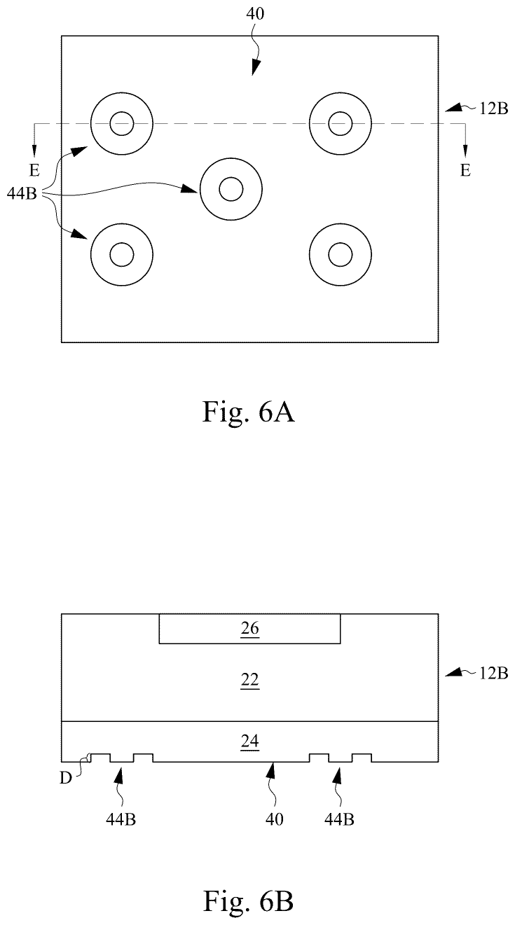

FIGS. 6A and 6B diagrammatically show isolation views of a representative semiconductor die 12B of a semiconductor die transfer structure 10 according to another embodiment. FIG. 6A diagrammatically shows a bottom isolation view of the semiconductor die 12B including the proximal surface 40 of the semiconductor die 12B, and FIG. 6B diagrammatically shows a sectional isolation view of the semiconductor die 12B taken along Section E-E indicated in FIG. 6A. The semiconductor die 12B of FIGS. 6A and 6B is identical to the semiconductor die 12 previously described, e.g., with reference to FIGS. 3A and 3B-except that recesses 44B in the proximal surface 40 of the semiconductor die 12B has a different cross-sectional geometry than the circular cross-section recesses 44 in the proximal surface 40 of the semiconductor die 12. The recesses 44B in the proximal surface 40 of the semiconductor die 12B are annular recesses. This advantageously increases the contact area between the silicon (or other material) of the proximal surface 40 of the semiconductor die 12B and the organic polymer of the distal ends 46 of the organic polymer pillars 36, thus (further) increasing the retention force holding the semiconductor die 12 to the bottom holder 14. The recesses 44B have an indicated recess depth D. In some embodiments, the annular recesses 44B have depth D that is greater than zero and is 6 microns or less. In some embodiments, the annular recesses 44B have depth D of between 0.5 micron and 6 microns. These are again merely nonlimiting illustrative examples of some suitable depths for certain specific implementations. The corresponding organic polymer pillars 36 may also have annular cross-sections matching the annular cross-section of the recesses 44B, although this is not required.

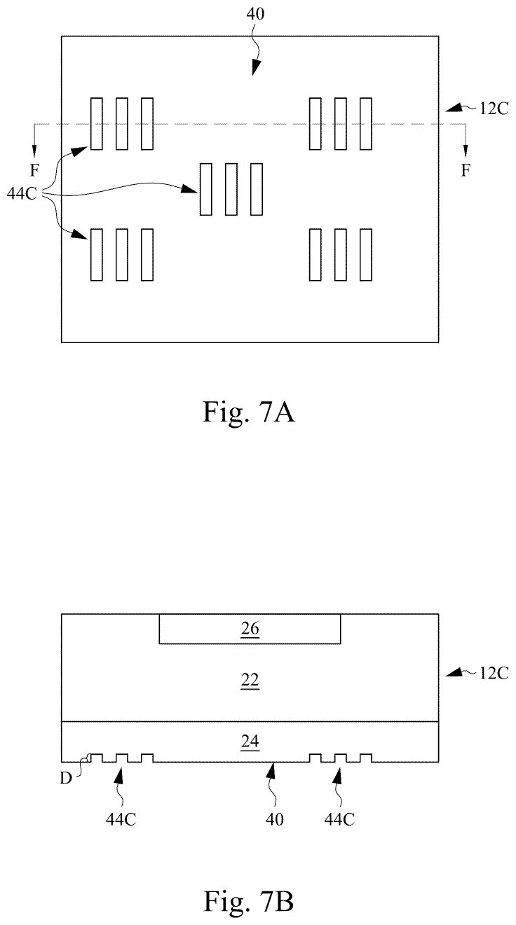

FIGS. 7A and 7B diagrammatically show isolation views of a representative semiconductor die 12C of a semiconductor die transfer structure 10 according to another embodiment. FIG. 7A diagrammatically shows a bottom isolation view of the semiconductor die 12C including the proximal surface 40 of the semiconductor die 12C, and FIG. 7B diagrammatically shows a sectional isolation view of the semiconductor die 12C taken along Section F-F indicated in FIG. 7A. The semiconductor die 12C of FIGS. 7A and 7B is identical to the semiconductor die 12 previously described, e.g., with reference to FIGS. 3A and 3B-except that recesses 44C in the proximal surface 40 of the semiconductor die 12C has a different cross-sectional geometry than the circular cross-section recesses 44 in the proximal surface 40 of the semiconductor die 12.

The recesses 44C in the proximal surface 40 of the semiconductor die 12C are parallel strip recesses. This advantageously increases the contact area between the silicon (or other material) of the proximal surface 40 of the semiconductor die 12C and the organic polymer of the distal ends 46 of the organic polymer pillars 36, thus (further) increasing the retention force holding the semiconductor die 12 to the bottom holder 14. The recesses 44C have an indicated recess depth D. In some embodiments, the parallel strip recesses 44C have depth D that is greater than zero and is 6 microns or less. In some embodiments, the parallel strip recesses 44C have depth D of between 0.5 micron and 6 microns. These are again merely nonlimiting illustrative examples of some suitable depths for certain specific implementations. The corresponding organic polymer pillars 36 may also have parallel strip cross-sections matching the parallel strip cross-section of the recesses 44C, although this is not required.

In the following, some further embodiments are described.

In a nonlimiting illustrative embodiment, an assembly comprises: a carrier wafer; semiconductor dies oriented with proximal surfaces of the semiconductor dies facing the carrier wafer; and pillars comprising an organic polymer material supporting the semiconductor dies on the carrier wafer. The pillars have distal ends filling recesses in the proximal surfaces of the semiconductor dies.

In a nonlimiting illustrative embodiment, a semiconductor die transfer method comprises: providing a semiconductor die transfer structure including a carrier wafer, semiconductor dies oriented with proximal surfaces of the semiconductor dies facing the carrier wafer, and pillars comprising an organic polymer material supporting the semiconductor dies on the carrier wafer, the pillars having distal ends filling recesses in the proximal surfaces of the semiconductor dies; and picking up a target semiconductor die of the semiconductor die transfer structure using a pick-and-place tool that electrostatically attracts the target semiconductor die to the pick-and-place tool and placing the target semiconductor die on a package surface.

In a nonlimiting illustrative embodiment, a semiconductor die transfer method comprises: providing a semiconductor die transfer structure including a carrier wafer, semiconductor dies oriented with proximal surfaces of the semiconductor dies facing the carrier wafer, and pillars comprising an organic polymer material supporting the semiconductor dies on the carrier wafer, the pillars having distal ends filling recesses in the proximal surfaces of the semiconductor dies; and picking up a target semiconductor die of the semiconductor die transfer structure using a pick-and-place tool that electrostatically attracts the target semiconductor die to the pick-and-place tool and placing the target semiconductor die on a package surface. The providing of the semiconductor die transfer structure includes: disposing a dielectric layer on the proximal surfaces of the semiconductor dies; etching openings in the dielectric layer and continuing the etching into the proximal surfaces of the semiconductor dies to form the recesses in the proximal surfaces of the semiconductor dies; bonding the dielectric layer to the carrier wafer using the organic polymer material wherein the polymer material also fills the openings in the dielectric layer and the recesses in the proximal surfaces of the semiconductor dies to form the pillars having distal ends filling the recesses in the proximal surfaces of the semiconductor dies; and removing the dielectric layer.

In a nonlimiting illustrative embodiment, a semiconductor structure comprises: a semiconductor die having a planar surface; and recesses in the planar surface of the semiconductor die. In some embodiments, the recesses in the planar surface of the semiconductor die have depths of between 0.5 micron and six microns. In some embodiments, the semiconductor die comprises a light emitting diode (LED) driver. In some embodiments, the recesses in the planar surface of the semiconductor die are circular recesses, annular recesses, cross-shaped recesses, or parallel strip recesses.

In a nonlimiting illustrative embodiment, an assembly for semiconductor die transfer includes a carrier wafer, semiconductor dies oriented with proximal surfaces thereof facing the carrier wafer, and pillars comprising an organic polymer material supporting the semiconductor dies on the carrier wafer. The pillars have distal ends filling recesses in the proximal surfaces of the semiconductor dies. A semiconductor die of the semiconductor die transfer structure is picked up using a pick-and-place tool. To fabricate the structure, a dielectric layer is disposed on the proximal surfaces of the semiconductor dies, and openings are etched in the dielectric layer and the etching is continued into the proximal surfaces of the semiconductor dies to form the recesses therein. The dielectric layer is bonded to the carrier wafer using the organic polymer material which also fills the openings in the dielectric layer and the recesses in the proximal surfaces of the semiconductor dies. The dielectric layer is removed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An assembly comprising:
a carrier wafer;
semiconductor dies oriented with proximal surfaces of the semiconductor dies facing the carrier wafer; and
pillars comprising an organic polymer material supporting the semiconductor dies on the carrier wafer, the pillars having distal ends filling recesses in the proximal surfaces of the semiconductor dies.

2. The assembly of claim 1, wherein the recesses in the proximal surfaces of the semiconductor dies have depths of between 0.5 micron and six microns.

3. The assembly of claim 1, further comprising;
a continuous layer of the organic polymer material disposed on the carrier wafer, wherein proximal ends of the pillars of the organic polymer connect with the continuous layer of the organic polymer material.

4. The assembly of claim 3, wherein:
the pillars have height H from the connection of the pillars with the continuous layer of the organic polymer material to the distal ends of the pillars,
the recesses in the proximal surfaces of the semiconductor dies have depth D, and
the pillars space the proximal surfaces of the semiconductor dies from the continuous layer of the organic polymer material a distance H-D.

5. The assembly of claim 1, wherein the recesses in the proximal surfaces of the semiconductor dies are circular recesses, annular recesses, cross-shaped recesses, or parallel strip recesses.

6. The assembly of claim 1, wherein the organic polymer material is benzocyclobutene (BCB).

7. The assembly of claim 6, wherein the carrier wafer is a silicon wafer.

8. The assembly of claim 7, wherein the semiconductor dies are light emitting diode (LED) drivers.

9. A semiconductor die transfer method comprising:
providing a semiconductor die transfer structure including a carrier wafer, semiconductor dies oriented with proximal surfaces of the semiconductor dies facing the carrier wafer, and pillars comprising an organic polymer material supporting the semiconductor dies on the carrier wafer, the pillars having distal ends filling recesses in the proximal surfaces of the semiconductor dies; and
picking up a target semiconductor die of the semiconductor die transfer structure using a pick-and-place tool that electrostatically attracts the target semiconductor die to the pick-and-place tool and placing the target semiconductor die on a package surface.

10. The semiconductor die transfer method of claim 9, wherein the providing includes:
disposing a dielectric layer on the proximal surfaces of the semiconductor dies;
etching openings in the dielectric layer and continuing the etching into the proximal surfaces of the semiconductor dies to form the recesses in the proximal surfaces of the semiconductor dies;
bonding the dielectric layer to the carrier wafer using the organic polymer material wherein the polymer material also fills the openings in the dielectric layer and the recesses in the proximal surfaces of the semiconductor dies to form the pillars having distal ends filling the recesses in the proximal surfaces of the semiconductor dies; and
removing the dielectric layer.

11. The semiconductor die transfer method of claim 10, wherein the bonding further forms a continuous layer of the organic polymer material on the carrier wafer.

12. The semiconductor die transfer method of claim 9, wherein the recesses in the proximal surfaces of the semiconductor dies are circular recesses, annular recesses, cross-shaped recesses, or parallel strip recesses.

13. The semiconductor die transfer method of claim 9, wherein the picking up of the target semiconductor die includes disengaging the distal ends of the pillars supporting the target semiconductor die from the recesses in the proximal surface of the target semiconductor die.

14. The semiconductor die transfer method of claim 9, wherein the organic polymer material is benzocyclobutene (BCB).

15. The semiconductor die transfer method of claim 9, wherein the semiconductor dies comprise light emitting diode (LED) drivers and the target LED driver is placed on a surface of an LED display.

16. The semiconductor die transfer method of claim 9, wherein the picking up of the target semiconductor die of the semiconductor die transfer structure using the pick-and-place tool is repeated to transfer a plurality of semiconductor dies from the semiconductor die transfer structure to the package surface.

17. A semiconductor structure comprising:
a semiconductor die having a planar surface; and
recesses in the planar surface of the semiconductor die.

18. The semiconductor structure of claim 17 wherein the recesses in the planar surface of the semiconductor die have depths of between 0.5 micron and six microns.

19. The semiconductor structure of claim 17 wherein the semiconductor die comprises a light emitting diode (LED) driver.

20. The semiconductor structure of claim 17, wherein the recesses in the planar surface of the semiconductor die are circular recesses, annular recesses, cross-shaped recesses, or parallel strip recesses.
